(19) United States
(12) Patent Application Publication
(10) Pub. No.: US 2002/0055250 A1
(43) Pub. Date: May 9, 2002

(54) DIELECTRIC STRUCTURE AND METHOD FOR MINIMIZING EROSION DURING CHEMICAL MECHANICAL POLISHING OF METALS

(76) Inventor: MANOJ K JAIN, PLANO, TX (US)

Correspondence Address: TEXAS INSTRUMENTS INCORPORATED, P O BOX 655474, M/S 3999, DALLAS, TX, 75265

(21) Appl. No.: 09/416,483

(22) Filed: Oct. 12, 1999

(51) Int. Cl. H01L 21/4763; H01L 21/302; H01L 21/461; H01L 23/48; H01L 23/52; H01L 29/40

(52) U.S. Cl. 438/624; 257/775; 438/637; 438/692

(57) ABSTRACT

A dielectric layer (110), such as an interlevel dielectric ILD or PMD, comprising a doped silicate glass layer (112) with an overlying CMP stopping layer (114). The CMP stopping layer (114) comprises a dielectric such as an undoped oxide. The CMP stopping layer (114) is resistant to dielectric erosion during a subsequent metal CMP step.

### FIELD OF THE INVENTION

The invention is generally related to the field of semiconductor processing and more specifically to a dielectric structure and method.

### BACKGROUND OF THE INVENTION

Chemical mechanical polishing (CMP) of Metals is increasingly becoming a popular process for applications such as fabrication of contacts, vias and interconnects. To fabricate contact and vias or interconnects, first the dielectric is patterned and etched to form contact/via holes or trenches. Then, one or more layers of thin films of barrier/liner materials are deposited. For example, TiN and/or Ti may be used. Then, a metal such as tungsten or aluminum is deposited to fill the holes or trenches. Metal can then be removed from the top surface by using CMP, leaving behind only metal in the holes or trenches.

Depending on the type of slurry and pad, the polishing can be selectively stopped in two ways: (A) stop on the liner material after complete removal of the metal from the top surface; and (B) stop on the dielectric after removing all the metal and liner materials from the top surface. For the interconnect application, removal of all the conducting liner materials is necessary. Therefore, a second polish is needed to remove the miner/barrier materials if the approach A is used. For the contacts/via applications, either a second polish can be performed to remove the liner materials, or it can be left on the top surface and allowed to become part of the upper metal interconnect level.

In the following, approach B is preferred because it is a single step CMP process and leads to a thinner metal stack for the contacts and via applications. The dissimilarity in the polishing rates of metals or metal containing compounds and dielectric is very important in this process. In the following, the ratio of polish rates of different materials is referred to as the “selectivity”. A high selectivity between the metals and dielectrics (large difference in polish rates) is very important in order to minimize the dielectric erosion during CMP. Minimizing dielectric erosion is critical due to the following reasons:

1. Dielectric erosion leads to reduction in the height of the contacts or vias and thinning of the interlevel dielectric layer. Thinning of the dielectric layer is undesirable since it can lead to insufficient insulation between the two metal levels.

2. Within wafer uniformity in polish rate (of both metals and dielectrics) is a concern in CMP. High non-uniformity can lead to variation in interlevel dielectric thickness across a wafer particularly if the selectivity to dielectric is poor. This can also lead to differences in via or contact heights also.

Unfortunately, some dielectrics have poor selectivity to metals for the commercially available slurries. For example, PMD (poly-metal dielectric) layers typically comprise BPSG. BPSG has poor selectivity to metals and is thus susceptible to dielectric erosion. Accordingly, there is a need to minimize dielectric erosion.

### SUMMARY OF THE INVENTION

The invention is a dielectric layer (such as an interlevel dielectric ILD or PMD) comprising a doped silicate glass layer with an overlying CMP stopping layer. The CMP stopping layer comprises a dielectric such as an undoped oxide. The CMP stopping layer is resistant to dielectric erosion during a metal CMP step.

An advantage of the invention is providing a dielectric layer with minimal dielectric erosion from CMP.

This and other advantages will be apparent to those of ordinary skill in the art having reference to the specification in conjunction with the drawings.

### BRIEF DESCRIPTION OF THE DRAWINGS

In the drawings:

FIG. 1 is a cross-sectional diagram of a first dielectric layer according to an embodiment of the invention;

FIG. 2 is a cross-sectional diagram of a second dielectric layer according to an embodiment of the invention;

FIG. 3 is a cross-sectional diagram of a third dielectric layer according to an embodiment of the invention;

FIGS. 4A-4C are cross-sectional diagrams of the first dielectric layer at various stages of fabrication.

### DETAILED DESCRIPTION OF THE EMBODIMENTS

The invention will now be described in conjunction with a process for forming a contact in a PMD layer. The invention may also be applied to forming vias in an ILD and/or forming trenches in an IMD (intrametal dielectric) for a damascene-type process.

A first dielectric layer 110 according to the invention is shown in FIG. 1. Dielectric layer 110 is shown as a PMD and is located over a semiconductor body 100. Semiconductor body 100 is typically a silicon substrate with or without epitaxial layers formed thereon. Transistors, such as transistor 102, and other devices (not shown) are located in or on semiconductor body 100.

Dielectric layer 110 comprises a doped oxide layer 112. The materials of doped oxide layer 112 is chosen to meet the performance specifications (e.g., dielectric constant, planarity, uniformity, the material of doped oxide layer 112 is chosen to meet the performance specification (e.g. void-free gap filling, mobile ion gettering capability, dielectric constant, thermal stability, etc.) of a PMD. For example, BPSG (boron-phosphorous doped silicate glass) or PSG (phosphorous doped silicate glass) may be used. The thickness of doped oxide layer 112 may be on the order of 4500 Å (e.g. 2000-6000 Å) over the polysilicon gate.

While doped oxides have material specific advantages that are beneficial for PMD, ILD, and IMD layers, they have poor selectivity to metal CMP processes required to form contacts, vias, and metal trenches. Poor selectivity to metal CMP results in dielectric erosion. Accordingly, dielectric layer 110 also comprises a stopping layer 114 overlying doped oxide layer 112. Stopping layer 114 comprises a material that is more resistant to metal CMP. For example, an undoped oxide may be used. PETEOS (plasma enhanced tetraethoxysilane) is used in the preferred embodiment. Stopping layer 114 is a much thinner layer than doped oxide layer 112. For example, stopping layer 114 may have a thickness in the range of 500-2000 Å. In the preferred embodiment, PETEOS at a thickness of approximately 1000 Å is used.

Materials, such as doped oxide 112, with poor selectivity to metal CMP can not entirely be replaced by high selectivity materials, such as that of stopping layer 114, in many applications because they may have material specific advantages. Therefore, a thin stopping layer 114 is used on top of the poor selectivity material without significantly altering the dielectric performance. For example, PETEOS has a significantly slower CMP polish rate than that of BPSG. In addition, the dry-etch rate and dielectric constant of PETEOS and BPSG are very similar. Thus, the erosion of the dielectric can be minimized with the used of PETEOS without affecting the capacitance and dielectric etch process significantly.

If an increase in dielectric constant can be tolerated, stopping layer 114 may alternatively comprise silicon nitride. If silicon nitride is used, the thickness may be in the range of 300-500 Å. However, separate etch steps may be needed to etch the stopping layer 114 and the doped oxide layer 112.

A contact 106 is located in dielectric layer 110. Alternatively, structure 106 may be a trench, which can be used to form a local interconnect. Contact 106 comprises a conductive material. Typically, tungsten, aluminum or copper is used for contact 106. Contact 106 may also include barrier layers as is known in the art. For example, Ti and/or TiN are typically used with aluminum.

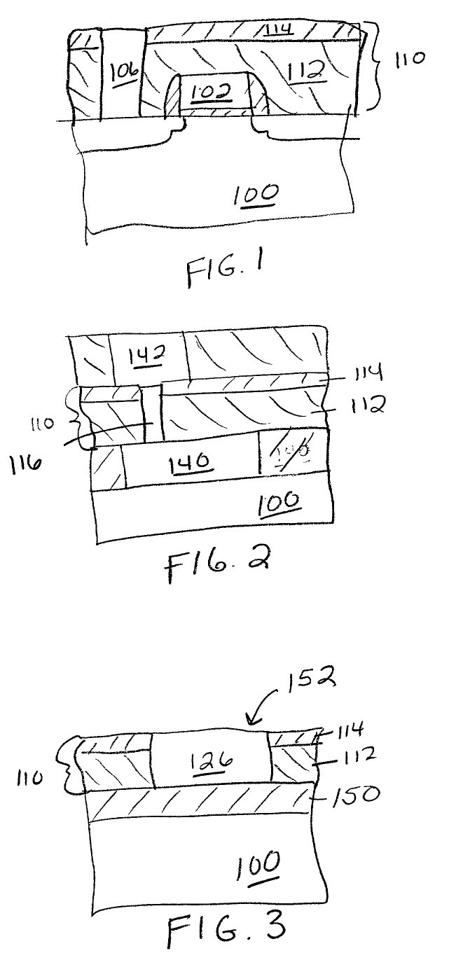

If dielectric layer 110 was instead an ILD, a via 116 would replace contact 106 as shown in FIG. 2. In this instance, doped oxide layer 112 may alternatively comprise FSG (fluorine doped silicate glass). FIG. 3 shows dielectric layer 110 as an IMD with a metal interconnect line 126 formed in a trench replacing contact 106. Again, doped oxide layer 112 may alternatively comprise FSG.

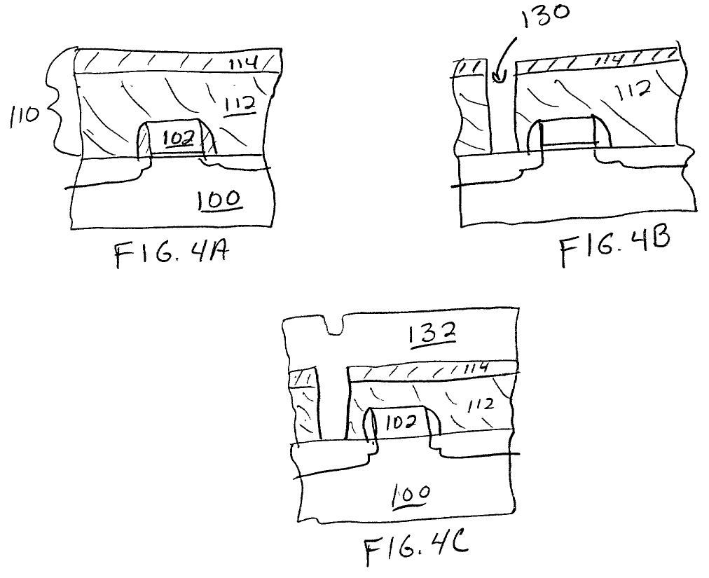

A method of forming dielectric layer 110 will now be described in conjunction with FIGS. 4A-4C. Semiconductor body 100 is processed through the formation of transistors 102 as is known in the art. Referring to FIG. 4A, doped oxide layer 112 is deposited over semiconductor body 100. It is desirable for doped oxide layer 112 to have a planar surface. Flowable oxides such as BPSG and PSG are typically used. However, if necessary or desired, doped oxide layer 112 may be polished using CMP for planarization. The thickness of doped oxide layer 112 is approximately 2000-6000 Å over the polysilicon gate of transistor 102 and thicker (e.g., ˜7000 Å) over the source and drain regions.

Stopping layer 114 is deposited over planarized doped oxide layer 112. Stopping layer 114 comprises a dielectric material that is more resistant to the subsequent metal CMP step to avoid dielectric erosion. For example, an undoped oxide may be used. PETEOS (plasma enhanced tetraethoxysilane) is used in the preferred embodiment. Stopping layer 114 is a much thinner layer than doped oxide layer 112. For example, stopping layer 114 may have a thickness in the range of 500-2000 Å. In the preferred embodiment, PETEOS at a thickness of approximately 1000 Å is used. If the increase in dielectric constant can be tolerated, stopping layer 114 may alternatively comprise silicon nitride. If silicon nitride is used, the thickness may be in the range of 300-500 Å.

Referring to FIG. 4B, a contact hole 130 is etched through stopping layer 114 and doped oxide layer 112. Alternatively, 130 could be a trench, which can form a local interconnect. If PETEOS and BPSG are used, respectively, then, the contact hole 130 may be etched in a single etch step. The contact hole 130 is then filled with conductive material 132 as shown in FIG. 4C. Conductive material 132 may, for example, comprise tungsten or aluminum with appropriate barrier layers.

In filling contact hole 130, conductive material 132 is also deposited over stopping layer 114. The portions of conductive material 132 over stopping layer 114 are removed using CMP, resulting in the structure of FIG. 1. Commercial slurries are available that offer high selectivity in polish rates between metal and metal-containing compounds of conductive material 132 and the material of stopping layer 114. Thus, the erosion of dielectric 110 is minimized during the CMP process. Greater than 10X selectivity between polish rates of conductive material and undoped oxide can be typically obtained using commonly available commercial slurries. A minimum selectivity value of 2X between the polish rates of conductive material and undoped oxide is highly desirable to minimize erosion of dielectric layer.

Subsequently, processing continues to form metal interconnect layers and packaging as is known in the art.

If dielectric layer 110 is to be used as an ILD, as shown in FIG. 2, a similar process may be used. Semiconductor body 100 is processed through the formation of at least one metal interconnect layer 140. A planarized doped oxide layer 112 is formed over the metal interconnect layer 140. In addition to the materials listed previously, FSG may be used for layer 112. A stopping layer 114 is formed over doped oxide layer 112. Then, a via 116 is etched through stopping layer 114 and doped oxide layer 112 to metal interconnect layer 140. Via 116 is then filled with a metal or metal-containing compound as is known in the art. For example, tungsten or aluminum with appropriate barriers may be used. The excess metal or metal-containing compound is removed by CMP. An appropriate slurry is used to provide a high selectivity between the metal and the material of stopping layer 114. The dielectric erosion in thus, minimized. Another metal interconnect layer 142 is formed over dielectric layer 110 and via 116.

If dielectric layer 110 is to be used an IMD, as shown in FIG. 3, a similar process may be used. Semiconductor body 100 is processed through the formation of transistors, PMD, and contacts. One or more metal interconnect layer may have also been formed. The planarized doped oxide layer 112 is formed over a dielectric material 150 at the surface of semiconductor body 100. Doped oxide layer 112 may, for example, comprise BPSG, PSG, or FSG. Dielectric material 150 may have contacts or vias formed therethrough. The stopping layer 114 is formed over doped oxide layer 112. Then, a trench 152 is etched through stopping layer 114 and doped oxide layer 112 to dielectric material 150. This is known as a damascene process. If desired, a dual damascene process may also be used to form a via in dielectric material 150, as is known in the art. Trench 152 is then filled with a metal or metal-containing compound as is known in the art. For example, copper with appropriate barriers may be used. The excess metal and liners are removed by CMP. An appropriate slurry is used to provide a high selectivity between the metal/liner and the material of stopping layer 114. The dielectric erosion in thus, minimized.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

In the claims:

1. A method for forming an integrated circuit, comprising the steps of:
forming a doped oxide layer over a semiconductor body;
forming a stopping layer comprising a dielectric material over said doped oxide layer;
patterning and etching a structure in said stopping layer and said doped oxide layer;
filling said structure with a conductive material; and
chemically-mechanically polishing said conductive material to remove said conductive material from a surface of said stopping layer, wherein said chemically-mechanically polishing step has a high selectivity between said conductive material and said stopping layer.

2. The method of claim 1, wherein said stopping layer comprises an undoped oxide.

3. The method of claim 1, wherein said structure is a via.

4. The method of claim 1, wherein said structure is a contact.

5. The method of claim 1, wherein said structure is a trench.

6. The method of claim 5, wherein said step of filling said structure forms a local interconnect in said trench.

7. A method of forming an integrated circuit, comprising the steps of:
forming a poly-metal dielectric (PMD) layer over a semiconductor body, said PMD layer comprising a stopping layer overlying a doped oxide layer, wherein said stopping layer comprises a dielectric material resistant to metal CMP;
patterning and etching a contact hole through said PMD layer;
filling said contact hole with a conductive material comprising metal; and
chemically-mechanically polishing said conductive material to remove said conductive material from over said PMD layer.

8. The method of claim 7, wherein said stopping layer comprises an undoped oxide.

9. The method of claim 7, wherein said stopping layer has a thickness in the range of 500-2000 Å.

10. An integrated circuit, comprising:
a dielectric layer having a stopping layer overlying a doped oxide layer; and
a conductive structure extending through said stopping layer and into said doped oxide layer.

11. The integrated circuit of claim 10, wherein said stopping layer comprises an undoped oxide.

12. The integrated circuit of claim 10, wherein said dielectric layer is a poly-metal dielectric (PMD) layer and said conductive structure is a contact.

13. The integrated circuit of claim 10, wherein said dielectric layer is a interlevel dielectric (ILD) layer and said conductive structure is a via.

14. The integrated circuit of claim 10, wherein said dielectric layer is a intra-metal dielectric (IMD) layer and said conductive structure is a interconnect line.

15. The integrated circuit of claim 10, wherein said dielectric layer is a poly-metal dielectric (PMD) layer and said conductive structure is a local interconnect.
